(19) United States
(12) Patent Application Publication
(10) Pub. No.: US 2012/0128948 A1
(43) Pub. Date: May 24, 2012

(54) COATED ARTICLE AND METHOD FOR MANUFACTURING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CHENG ZHANG, Shenzhen City (CN)

(73) Assignees: HON HAI PRECISION INDUSTRY CO., LTD., Tu-Cheng (TW); HON FU JIN PRECISION INDUSTRY (ShenZhen) CO., LTD., Shenzhen City (CN)

(21) Appl. No.: 13/169,697

(22) Filed: Jun. 27, 2011

(30) Foreign Application Priority Data
Nov. 23, 2010 (CN) 201010555189.2

(51) Int. Cl. B32B 3/10; C23C 14/34

(52) U.S. Cl. 428/201; 428/209; 204/192.12; 204/192.15

(57) ABSTRACT

A coated article includes a substrate; a color layer deposited on the substrate; and a pattern layer deposited on the surface of the color layer opposite to the substrate. A network of metal nuclei groups forms the pattern layer. The network of metal nuclei groups includes a plurality of metal nuclei, and each metal nucleus is bonded to at least one other metal nucleus.

### BACKGROUND

1. Technical Field

The exemplary disclosure generally relates to coated articles and methods for manufacturing the coated articles.

2. Description of Related Art

Vacuum deposition is used to form a thin film or coating on housings of portable electronic devices, to improve abrasion resistance, but typical vacuum deposition cannot deposit a coating having an attractive appearance on the housing. A typical way to improve the appearance of the coating is using a laser engraving machine to etch a pattern on the coating. However, if a laser engraving machine is used to etch a pattern on the coating, the cost of manufacturing the housing will increase.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary embodiment of a coated article and method for manufacturing the coated article. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an embodiment of a coated article.

FIG. 2 illustrates a plan and perspective view of the coated article of FIG. 1.

FIG. 3 is a diagram for manufacturing the article in FIG. 1.

FIG. 4 is a schematic view of a magnetron sputtering coating machine for manufacturing the coated article in FIG. 1.

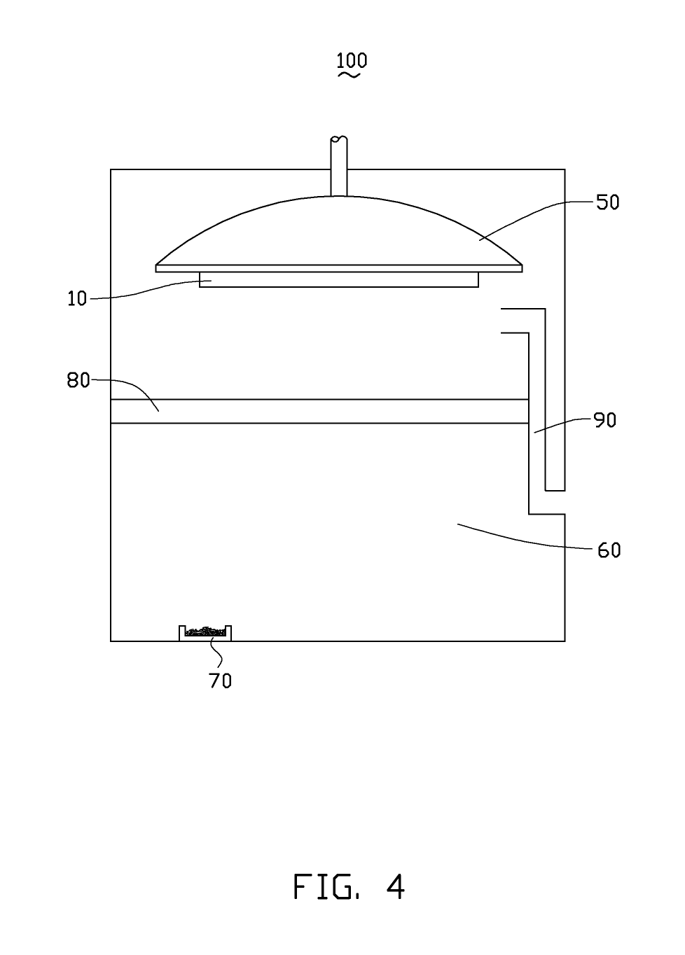

### DETAILED DESCRIPTION

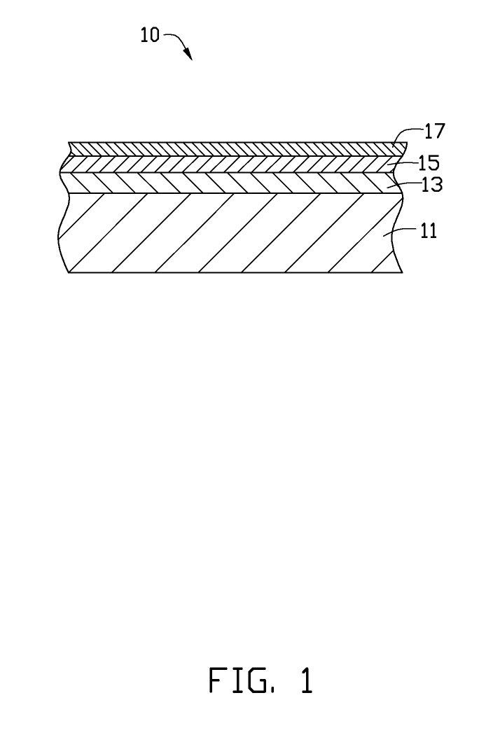

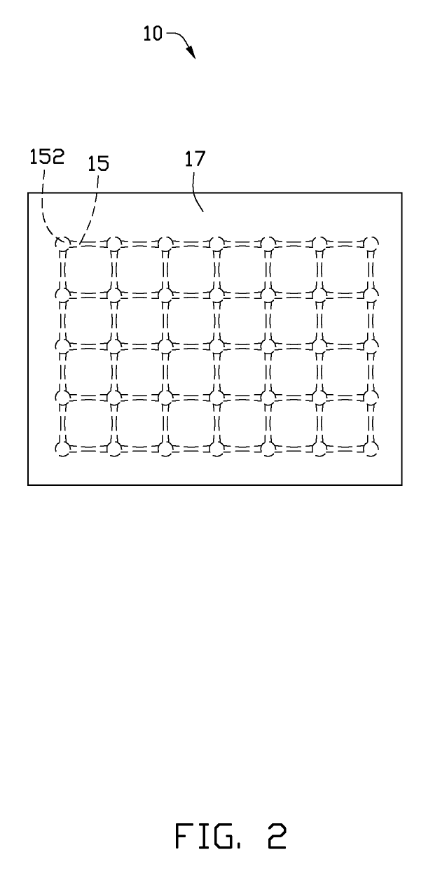

Referring to FIG. 1, an exemplary embodiment of a coated article 10 manufactured, by a coating process, such as by vacuum deposition, and includes a substrate 11, a color layer 13 deposited on the substrate 11, a pattern layer 15 deposited on the color layer 13 opposite to the substrate 11 and a protection layer 17 deposited on the pattern layer 15 opposite to the color layer 13. The coated article 10 may be a housing of an electronic device. The substrate 11 may be made of stainless steel, glass, plastic or ceramic. The color layer 13 may be titanium-nitride layer, chromium-nitride layer or zirconium-nitride layer. A network of metal nuclei group, which includes a plurality of metal nuclei 152 (FIG. 2), may form the pattern layer 15 and each metal nucleus 152 is bonded to at least one neighboring metal nucleus 152 around it. The network of nuclei groups may be a network of titanium nuclei groups, a network of chromium nuclei groups or a network of zirconium nuclei groups. The protection layer 17 may be aluminum-oxide layer, silicone-oxide layer or zirconium-oxide layer.

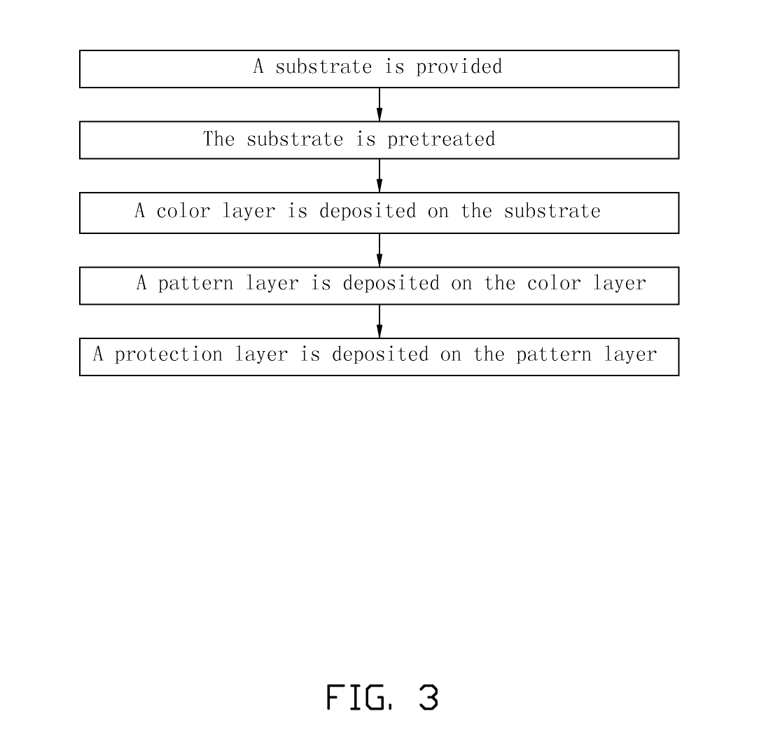

Referring to FIGS. 2 and 3, a method for manufacturing the coated article 10 manufactured by vacuum deposition may include at least the following steps.

A substrate 11 is provided. The substrate 11 may be made of stainless steel, glass, plastic or ceramic.

The substrate 11 is pretreated. For example, the substrate 11 may be washed with a solution (e.g., alcohol or acetone) in an ultrasonic cleaner, to remove, e.g., grease, dirt, and/or impurities. The substrate 11 is then dried. The substrate 11 may also be cleaned using argon plasma cleaning.

A color layer 13 is deposited on the substrate 11 by magnetron sputtering. The substrate 11 is retained on a rotating bracket 50 in a vacuum chamber 60 of a magnetron sputtering coating machine 100. The vacuum level inside the vacuum chamber 60 is adjusted to 3.0×10⁻⁸ Pa. The temperature inside the vacuum chamber 60 is adjusted between 100 degrees Celsius (° C.) and 200° C. Pure argon is fed into the vacuum chamber 60 at a flux between about 100 Standard Cubic Centimeters per Minute (sccm) to about 400 sccm from a gas inlet 90. Nitrogen is fed into the vacuum chamber 60 at a flux between about 2 sccm to about 4 sccm from the gas inlet 90. The substrate 11 is rotated at 3 revolutions per minute (rpm). A target 70, such as titanium target, chromium target or zirconium target, in the vacuum chamber 60 is evaporated at a power between about 4 kW and about 9 kW. A bias voltage applied to the substrate 11 is in a range between about −100 and about −300 volts with a duty cycle of 30˜70% for about 10 minutes to about 40 minutes, to deposit the color layer 13 on the substrate 11.

A pattern layer 15 is deposited on the color layer 13 by magnetron sputtering. A shielding board 80 is located between the target 70 and the substrate 11. The vacuum level inside the vacuum chamber 60 is adjusted to 3.0×10⁻⁸ Pa. The substrate 11 is heated in a range between 500° C. and 800° C. Pure argon is fed into the vacuum chamber 60 at a flux between about 100 sccm to about 400 sccm from the gas inlet 90. The substrate 11 is rotated at 3 rpm. A bias voltage applied to the substrate 11 is in a range between about −100 and about −300 volts with a duty cycle of 30˜70%. The target 70 is evaporated at a power between about 4 kW and about 9 kW. At this time, because the shielding board 80 is located between the target 70 and the substrate 11 atoms, sputtered from the target 70 cannot arrive to the substrate 11. After the target 70 is evaporated at a power between about 4 kW and about 9 kW for between about 1 minute and about 3 minutes, the speed and the amount of the target atoms become steady. The shielding board 80 is removed. Then target atoms sputtered from the target 70 are deposited on the color layer 13 at a high-speed. After the target 70 is continuously evaporated at a power between about 4 kW and about 9 kW for between about 1 minute and about 5 minutes, the growth of depositing the target atoms from the target 70 on the color layer 13 undergo nucleation, in which nuclei continuously grow to form network of patterns, with contacting neighboring nuclei. At this time, the target atoms from the target 70 are arriving at the surface of the color layer 13 and lose thermal energy to the color layer 13, and the color layer 13 absorbs that energy. Depending on the thermal energy of the target atoms and the color layer 13, the target atoms move from one point to another point on the surface of the color layer until they lose the thermal energy required to move from one point to another point on the surface of the color layer 13, thereby forming a plurality of nuclei 152 on the color layer 13. As the nuclei 152 continue to form, the nuclei 152 grow into a network of nuclei groups to form the pattern layer 15 on the surface of the color layer 13.

A protection layer 17 is deposited on the pattern layer 15 by magnetron sputtering, to improve the corrosion resistance of the pattern layer 15. The vacuum level inside the vacuum chamber 60 is adjusted to 3.0×10⁻⁸ Pa. The temperature in the vacuum chamber 60 is adjusted to be in a range between 100° C. and 200° C. Pure argon is fed into the vacuum chamber 60 at a flux between about 100 sccm to about 400 sccm from the gas inlet 90. Oxygen is fed into the vacuum chamber 60 at a flux between about 20 sccm to about 150 sccm from the gas inlet 90. The substrate 11 is rotated at 3 rpm. The target 70 is evaporated at a power between about 5 kW and about 12 kW. A bias voltage applied to the substrate 11 is in a range between about −100 and about −300 volts with a duty cycle of 3070% for about 5 minutes to about 30 minutes, to deposit the protection layer 17 on the pattern layer 15.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a substrate; a color layer deposited on the substrate; and
a pattern layer deposited on the surface of the color layer opposite to the substrate, the pattern layer is formed by a network of metal nuclei group, the network of metal nuclei group including a plurality of metal nuclei, and each metal nucleus being bonded to at least one other metal nucleus.

2. The coated article as claimed in claim 1, wherein the network of metal nuclei group is network of titanium nuclei group, network of chromium nuclei group or network of zirconium nuclei group.

3. The coated article as claimed in claim 1, wherein the substrate is made of stainless steel, glass, plastic or ceramic.

4. The coated article as claimed in claim 1, wherein the color layer is titanium-nitride layer, chromium-nitride layer or zirconium-nitride layer.

5. The coated article as claimed in claim 1, further comprising a protection layer deposited on the pattern layer opposite to the color layer.

6. The coated article as claimed in claim 5, wherein the protection layer is aluminum-oxide layer, silicone-oxide layer or zirconium-oxide layer.

7. A method for manufacturing a coated article comprising steps of:
providing a substrate; and
depositing a color layer on the substrate by magnetron sputtering; and
depositing a pattern layer on the surface of the color layer, wherein the substrate is retained in a vacuum chamber with a metal target located therein; a shielding board is located between the metal target and the substrate; the substrate is heated in a range between 500° C. and 800° C.; the metal target is evaporated; after the metal target is evaporated for between about 1 minute and about 3 minutes, the shielding board is removed and the metal target is continuously evaporated for between about 1 minute and about 5 minutes causing the growth of depositing atoms sputtered from the metal target on the surface of the color layer to undergo nucleation to form the pattern layer on the surface of the color layer.

8. The method of claim 7, wherein the substrate is made of stainless steel, glass, plastic or ceramic.

9. The method of claim 7, wherein the metal target is titanium target, chromium target or zirconium target.

10. The method of claim 9, wherein the color layer is titanium-nitride layer, chromium-nitride layer or zirconium-nitride layer.

11. The method of claim 10, wherein during depositing the color layer on the substrate, the vacuum level inside the vacuum chamber is adjusted to 3.0×10⁻⁸ Pa; the temperature inside the vacuum chamber is adjusted between 100° C. and 200° C.; pure argon is fed into the vacuum chamber at a flux between about 100 sccm to about 400 sccm; nitrogen is fed into the vacuum chamber at a flux between about 2 sccm to about 4 sccm; the metal target is evaporated at a power between about 4 kW and about 9 kW; a bias voltage applied to the substrate is in a range between about −100 and about −300 volts with a duty cycle of 30˜70% for about 10 minutes to about 40 minutes, to deposit the color layer on the substrate.

12. The method of claim 9, wherein the pattern layer is a network of metal nuclei group.

13. The method of claim 12, wherein the network of metal nuclei group is network of titanium nuclei group, network of chromium nuclei group or network of zirconium nuclei group.

14. The method of claim 13, wherein during depositing the pattern layer on the surface of the color layer, the vacuum level inside the vacuum chamber is adjusted to 3.0×10⁻⁸ Pa; pure argon is fed into the vacuum chamber at a flux between about 100 sccm to about 400 sccm; a bias voltage applied to the substrate is in a range between about −100 and about −300 volts with a duty cycle of 30˜70%; the metal target is evaporated at a power between about 4 kW and about 9 kW.

15. The method of claim 14, wherein after the shielding board is removed, atoms sputtered from the metal target are arriving at the color layer lose thermal energy to the color layer, and the color layer absorbs that energy; depending on the thermal energy of the atoms sputtered from the metal target and the color layer, the atoms sputtered from the metal target move on the surface of the color layer until they lose the thermal energy required to move from one point to another point on the surface of the color layer, thereby forming a plurality of metal nuclei in the color layer; as the metal nuclei continue to form, the metal nuclei grow into the network of metal nuclei group to form the pattern layer on the surface of the color layer.

16. The method of claim 9, further comprising depositing a protection layer on the pattern layer by magnetron sputtering, to improve a corrosion resistance of the pattern layer.

17. The method of claim 16, wherein the protection layer is aluminum-oxide layer, silicone-oxide layer or zirconium-oxide layer.

18. The method of claim 17, wherein during depositing the protection layer on the pattern layer, the vacuum level inside the vacuum chamber is adjusted to 3.0×10⁻⁸ Pa; the temperature in the vacuum chamber is adjusted to be in a range between 100° C. and 200° C.; pure argon is fed into the vacuum chamber at a flux between about 100 sccm to about 400 sccm; oxygen is fed into the vacuum chamber at a flux between about 20 sccm to about 150 sccm; the metal target is evaporated at a power between about 5 kW and about 12 kW; a bias voltage applied to the substrate is in a range between about −100 and about −300 volts with a duty cycle of 30˜70% for about 5 minutes to about 30 minutes, to deposit the protection layer on the pattern layer.
